(19) United States
(12) Patent Application Publication
(10) Pub. No.: US 2009/0071538 A1
(43) Pub. Date: Mar. 19, 2009

(54) PHOTOVOLTAIC DEVICE AND METHOD OF MANUFACTURING THE SAME

(76) Inventors: Moon-Jae Lee, Yongin-si (KR); Byung-Jun Jung, Yongin-si (KR)

Correspondence Address: CHRISTIE, PARKER & HALE, LLP, PO BOX 7068, PASADENA, CA, 91109-7068, US

(21) Appl. No.: 12/036,061

(22) Filed: Feb. 22, 2008

(30) Foreign Application Priority Data
Sep. 17, 2007 (KR) 10-2007-0094177

(51) Int. Cl. H01L 31/0232; H01L 31/04; H01L 31/18

(52) U.S. Cl. 136/257; 438/72; 257/E31.127

(57) ABSTRACT

A photovoltaic device having a relatively high photoelectric efficiency and a method of manufacturing the same. The photovoltaic device according to an embodiment of the present invention includes a transparent electrode, a metal electrode, and a plurality of photovoltaic layers between the transparent electrode and the metal electrode. The photovoltaic layers include light-absorbing compounds for absorbing different light absorption wavelength bands, and each of the photovoltaic layers comprises an electron accepting material. As such, a photovoltaic device according to an embodiment of the present invention includes a plurality of photovoltaic layers having different light absorption regions, and thereby having relatively high photoelectric efficiency.

### CROSS-REFERENCE TO RELATED APPLICATION

This application claims priority to and the benefit of Korean Patent Application No. 10-2007-0094177, filed in the Korean Intellectual Property Office on Sep. 17, 2007, the entire content of which is incorporated herein by reference.

### BACKGROUND OF THE INVENTION

1. Field of the Invention

The present invention relates to a photovoltaic device and a method of manufacturing the same.

2. Description of the Related Art

Photovoltaic devices can transform light signals into electrical signals and can be applied to diverse fields such as sensors, solar cells, and the like. Photovoltaic devices are not only environmentally friendly but also have many other advantages such as being a sustainable energy source, having a long life-span, and the like. As such, photovoltaic devices are being actively researched. However, due to limits in improving photovoltaic device efficiency, photovoltaic devices have been difficult to commercialize.

A photovoltaic device includes an inorganic semiconductor composed of monocrystalline, polycrystalline, amorphous silicon, or compounds such as CuInSe, GaAs, CdS, and so on as an electromotive power material. The photovoltaic device including the inorganic semiconductor has comparatively high energy transformation efficiency that ranges from 10 to 20%, and accordingly can be used as a power source for remote devices and as an assistant power source for small portable electronic devices. However, since the photovoltaic device including the inorganic semiconductor is typically fabricated by a plasma CVD method or a high temperature crystal growth process, it requires a lot of energy during the process. In addition, since the photovoltaic device including the inorganic semiconductor may include environmentally harmful materials such as Cd, As, Se, and the like, it may harm the environment when it is discarded.

To solve the above described problems, an organic solar cell including an organic semiconductor has been suggested as a new photovoltaic device. Since the organic semiconductor has a variety of material choices, low toxicity, good productivity, low cost, and plasticity, it has been actively researched so that an organic solar cell including the organic semiconductor can be put to use.

Also, an organic solar cell can be categorized as either a semiconductor cell or a dye-sensitized cell. The semiconductor cell can be further categorized as a Schottky type cell or a pn-conjunction type cell, depending on its mechanisms for separating a pair of charges produced by light. The Schottky type cell uses an internal electric field formed by a Schottky wall on the contacting side of an organic semiconductor and a metal. The pn-conjunction type cell can be further categorized as an organic/organic pn-conjunction type cell using an organic material for both of the pn semiconductors or an organic/inorganic pn-conjunction type cell using an inorganic material for one of the pn semiconductors and an organic material for the other one of the pn semiconductors. Currently, the pn-conjunction type cell does not have sufficient photoelectric efficiency and requires a film deposition process.

Therefore, there is still a need to further improve the photoelectric efficiency of a photovoltaic device.

### SUMMARY OF THE INVENTION

An aspect of an embodiment of the present invention is directed toward a photovoltaic device having a high photoelectric efficiency.

Another aspect of an embodiment of the present invention is directed toward a method of manufacturing the photovoltaic device having the high photoelectric efficiency.

An embodiment of the present invention provides a photovoltaic device that includes a transparent electrode, a metal electrode, and a plurality of photovoltaic layers between the transparent electrode and the metal electrode. The photovoltaic layers include light-absorbing compounds for absorbing different light absorption wavelength bands, and each of the photovoltaic layers comprises an electron accepting material.

In one embodiment, the photovoltaic layer includes a first photovoltaic layer including a short-wavelength absorption compound on the transparent electrode, and a second photovoltaic layer including a long-wavelength absorption compound on the metal electrode.

In one embodiment, a thickness ratio between the first photovoltaic layer including the short-wavelength absorption compound and the second photovoltaic layer including the long-wavelength absorption compound ranges from about 1:1 to about 1:3.

In one embodiment, the first photovoltaic layer including the short-wavelength absorption compound has a thickness ranging from about 30 nm to about 150 nm.

In one embodiment, the short-wavelength absorption compound is for absorbing light having a wavelength ranging from about 400 nm to about 600 nm.

In one embodiment, the short-wavelength absorption compound includes a hydrophilic conductive compound selected from the group consisting of a polyphenylenevinylene-based polymer, a pentacene compound, and mixtures thereof.

In one embodiment, the short-wavelength absorption compound is included in the first photovoltaic layer in an amount ranging from 20 to 400 parts by weight based on 100 parts by weight of the electron accepting material.

In one embodiment, the second photovoltaic layer including the long-wavelength absorption compound has a thickness ranging from about 30 nm to about 200 nm.

In one embodiment, the long-wavelength absorption compound is for absorbing light having a wavelength ranging from about 400 nm to about 900 nm.

In one embodiment, the long-wavelength absorption compound includes a non-hydrophilic conjugated polymer selected from the group consisting of a thiophene-based polymer, a dithiophene-based polymer, and mixtures thereof.

In one embodiment, the long-wavelength absorption compound is included in the second photovoltaic layer in an amount ranging from 20 to 400 parts by weight based on 100 parts by weight of the electron accepting material.

The electron accepting material may be selected from the group consisting of fullerene, fullerene derivatives, perylene, carbon nanotubes, semiconductor nanoparticles, and mixtures thereof.

The photovoltaic device may further include a buffer layer including a material with a working voltage of 5.2 eV or less between the transparent electrode and the photovoltaic layer, or between the photovoltaic layer and the metal electrode.

The material in the buffer layer may be selected from the group consisting of poly(3,4-ethylenedioxythiophene), poly(styrene-sulfonate), and mixtures thereof.

The photovoltaic device may further include an inter-electrode including a material with a working voltage of 5.2 eV or less between the photovoltaic layers.

The photovoltaic device may further include an electron injection layer between the photovoltaic layer and the metal electrode, or between the buffer layer and the metal electrode.

The electron injection layer may include a material selected from the group consisting of calcium, lithium derivatives, and mixtures thereof.

The photovoltaic device may be a solar cell or an organic optical sensor.

An embodiment of the present invention provides a method of manufacturing a photovoltaic device. The method includes forming a transparent electrode on a transparent substrate; forming a first photovoltaic layer including a short-wavelength absorption compound on the transparent electrode; forming a second photovoltaic layer including a long-wavelength absorption compound on the first photovoltaic layer; and forming a metal electrode on the second photovoltaic layer.

The method may further include a plasma surface treatment after the forming of the first photovoltaic layer.

As such, a photovoltaic device according to an embodiment of the present invention includes a plurality of photovoltaic layers having different light absorption regions, and thereby having relatively high photoelectric efficiency.

Also, a manufacturing method according to an embodiment of the present invention allows for disposing a plurality of photovoltaic layers in a photovoltaic device, for uniformly surface-modifying a photovoltaic layer during the plasma surface treatment and thereby generating no pin holes and no dark current, and/or for preventing (or reducing) deterioration of electron conductivity of the surface-treated photovoltaic layer.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a partial cross-sectional view illustrating a photovoltaic device in accordance with an embodiment of the present invention.

FIG. 2 is a flow chart schematically showing a manufacturing method of a photovoltaic device according to an embodiment of the present invention.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification.

In the context of an embodiment of the present invention, a photovoltaic device includes a photovoltaic layer between a transparent electrode and a metal electrode. The photovoltaic layer includes an electron donating material and an electron accepting material. When light is provided through a transparent electrode, electrons move from the electron donating material to the electron accepting material and are thereby separated from their corresponding holes.

The separated electrons and holes are respectively injected (or transported) into the transparent electrode and the metal electrode, thereby producing energy.

The photovoltaic layer is formed by a dry thin film method or a wet thin film method.

The dry thin film method can be used to easily form many different thin films into a multi-stack, but needs a complicated process such as vacuum treatment. It may also be difficult to form a thin film with a large area and a uniform thickness using the dry thin film method.

On the other hand, the wet thin film method can form a thin film with a large area in a relatively simple process. However, since it uses a solvent, the wet thin film method may not be suitable for multi-layered coating unless the solvent has appropriate characteristics for surface modification to prepare a device with multi-layers.

Accordingly, an embodiment of the present invention provides a plasma surface treatment to modify the surface of a photovoltaic layer so that a plurality of photovoltaic layers can be disposed using, e.g., the wet thin film method. As a result, the embodiment of the present invention can improve photoelectric efficiency of a photovoltaic device including the photovoltaic layers.

The photovoltaic device according to an embodiment of the present invention includes a transparent electrode, a metal electrode, and a plurality of photovoltaic layers disposed between the transparent electrode and the metal electrode.

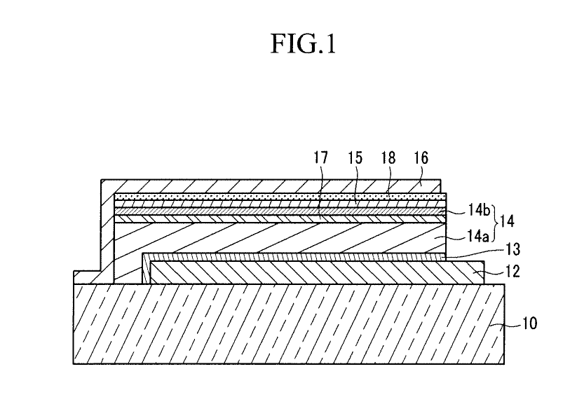

FIG. 1 is a partial cross-sectional view illustrating a photovoltaic device in accordance with an embodiment of the present invention.

As shown in FIG. 1, the photovoltaic device 1 includes (in sequential order) a transparent electrode 12, a photovoltaic layer 14, and a metal electrode 16 on a transparent substrate 10. This photovoltaic device 1 can be suitably applied to an organic solar cell, an organic light emitting diode, an organic thin film transistor, an organic optical sensor, and the like, which absorb solar energy and generate electrical energy.

The transparent substrate 10 may include any suitable material as long as it is suitably transparent and/or can accept external light. The transparent substrate 10 can be glass and/or plastic. In particular, the plastic may include polyethylene terephthalate (PET), polyethylene naphthalate (PEN), polycarbonate (PC), polypropylene (PP), polyimide (PI), triacetyl cellulose (TAC), or copolymers thereof.

In one embodiment, the transparent electrode 12 includes a material with a low work function. In one embodiment, the transparent electrode 12 also includes a transparent conductive metal oxide such as indium tin oxide (ITO), fluorine tin oxide (FTO), indium zinc oxide (IZO), ZnO-(Ga₂O₃ or Al₂O₃), and the like, so that it can be transparent and/or accept light. In particular, the transparent electrode 12 may include SnO₂ having relatively high conductivity, transparency, and heat resistance; or ITO having a relatively low price.

The metal electrode 16 includes a metal with a higher work function than the transparent electrode 12. Specifically, the metal electrode 16 is formed of a single layer including Al (aluminum), Ca (calcium), Ag (silver), Au (gold), Pt (platinum), or Ni (nickel), or of multiple layers including various suitable metal layers.

The photovoltaic layer 14 formed on the transparent electrode 12 includes an electron donor (a p-type semiconductor) and an electron accepter (an n-type semiconductor). In addition, the photovoltaic layer 14 is formed through a heterojunction of the electron donor and the electron acceptor or as multi-layers alternately stacked with an electron donor layer and an electron acceptor layer.

According to one embodiment of the present invention, the photovoltaic layer 14 has a multi-layered structure including light-absorbing compounds for absorbing different light-absorbing wavelengths. FIG. 1 shows a photovoltaic layer 14 with two layers, but the present invention is not limited thereto and it can have more than two layers.

Referring to FIG. 1, the photovoltaic layer 14 includes a first photovoltaic layer 14a including a short-wavelength absorption compound as an electron accepting material and an electron donating material, and a second photovoltaic layer 14b including a long-wavelength absorption compound as an electron accepting material and an electron-donating material.

The first photovoltaic layer 14a including the short-wavelength absorption compound may be positioned at the side of the transparent electrode 12 where light is provided. The second photovoltaic layer 14b including the long-wavelength absorption compound may be positioned at the side of the metal electrode 16. Since light having a long wavelength has better transmission than a light having a short wavelength, the long-wavelength absorption material may be disposed behind the light-providing side, when solar light is provided into the photovoltaic device.

In addition, the first and second photovoltaic layers 14a, 14b may have a thickness ratio ranging from about 1:1 to about 1:3 (or from 1:1 to 1:3). In one embodiment, the first and second photovoltaic layers 14a, 14b have a thickness ratio ranging from 1:1 to 1:2. When the first and second photovoltaic layers 14a, 14b have a ratio out of the above range, for example when the first photovoltaic layer 14a is much thicker than the second photovoltaic layer 14b, this may limit charge movement due to low conductivity of the photovoltaic layers 14a, 14b. On the other hand, when the first photovoltaic 14a layer is much thinner than the second photovoltaic layer 14b, the second photovoltaic layer 14b may not appropriately absorb enough light.

The first photovoltaic layer 14a may have a thickness ranging from about 30 nm to about 150 nm (or from 30 nm to 150 nm) within the above ratio range. In one embodiment, the first photovoltaic layer 14a has a thickness ranging from 50 to 100 nm. When the first photovoltaic layer 14a has a thickness of less than 30 nm, it may not properly absorb solar light. When the first photovoltaic layer 14a has a thickness of more than 150 nm, it may limit charge movement.

In addition, the second photovoltaic layer 14b may have a thickness ranging from about 30 nm to about 200 nm (or from 30 nm to 200 nm) within the above ratio range. In one embodiment, the second photovoltaic layer 14b may have a thickness ranging from 100 to 150 nm. When the second photovoltaic layer 14b has a thickness of less than 30 nm, it may not appropriately absorb solar light. When the second photovoltaic layer 14b has a thickness of more than 200 nm, it may limit charge movement.

Further, the first photovoltaic layer 14a may include a polymer for absorbing a wavelength region ranging from about 400 nm to about 600 nm (or from 400 nm to 600 nm) as a short-wavelength absorption compound. In particular, the first photovoltaic layer 14a may be composed of a polymer selected from the group consisting of a hydrophilic conductive polymer such as a polyphenylenevinylene-based polymer, a pentacene compound, and mixtures thereof. According to another embodiment of the present invention, the first photovoltaic layer 14a may be composed of a polymer selected from the group consisting of poly(2-methoxy-5-(3,7-dimethoxyoctyloxy)-1,4-phenylene-vinylene)(poly(2-methoxy-5-3,7-dimethyloctyloxy)-1,4-phenylene-vinylene (MDMO-PPV), pentacene, and mixtures thereof.

The short-wavelength absorption compound may be included in an amount ranging from 20 to 400 parts by weight based on 100 parts by weight of an electron accepting material. In one embodiment, the short-wavelength absorption compound is included in an amount ranging from 80 to 100 parts by weight based on 100 parts by weight of the electron accepting material. When the short-wavelength absorption compound is included in an amount that is less than 20 parts by weight, it may have a low short-wavelength absorption rate. In general, charges are produced and separated on the pn conjunction interface. When there are relatively much more p-type semiconductors than there are n-type semiconductors (or when the weighted parts of the electron donating material is much more than the weighted parts of the electron accepting material), that is, when the short-wavelength absorption compound is included at more than 400 parts by weight, it may deteriorate charge separation efficiency.

Also, the second photovoltaic layer 14b includes a long-wavelength absorption compound as aforementioned. The higher the wavelength absorption region, the better the device characteristics that can be accomplished. In particular, the long-wavelength absorption compound may include a material for absorbing a wavelength region ranging from about 400 nm to about 900 nm (or from 400 nm to 900 nm). In one embodiment, the long-wavelength absorption compound includes a material for absorbing a wavelength region ranging from 600 to 900 nm. Specifically, in one embodiment, the long-wavelength absorption compound includes a non-hydrophilic copolymer selected from the group consisting of a thiophene-based polymer, a dithiophene-based polymer, and mixtures thereof. More specifically, it may include an alkylpolythiophene such as poly(3-hexylthiophene) (P3HT), poly(3-octylthiophene) (P3OT), and the like, poly-2,6-(4,4-bis-(2-ethylhexyl)-4H-cyclopenta[2,1-b;3,4-b′]-dithiophene)-alt-4,7-(2,1,3-benzothiadiazole) (PCPDTBT), and mixtures thereof.

The long-wavelength absorption compound may be included in an amount ranging from 20 to 400 parts by weight based on 100 parts by weight of an electron accepting material. When the long-wavelength absorption compound is included in an amount of less than 20 parts by weight, it may have a low long-wavelength absorption rate. When the long-wavelength absorption compound is included in an amount of more than 400 parts by weight, it may deteriorate charge separation efficiency.

In the first and second photovoltaic layers 14a, 14b, an electron accepting material may be selected from the group consisting of fullerene (C₆₀) with a high affinity for electrons; fullerene derivatives such as 1-(3-methoxy-carbonyl)propyl-1-phenyl(6,6)C61 (PCBM); perylene; carbon nanotubes; semiconductive nanoparticles such as CdTe, CdSe, and the like; and mixtures thereof. Here, the fullerene is usually synthesized with a semiconductor polymer, or is applied to multiple layers.

The present invention is illustrated based on the embodiment of a double-layered photovoltaic layer, but is not limited thereto. Accordingly, it can be embodied as a multi-layered photovoltaic layer with more than two layers.

In addition, the present invention may further include a buffer layer (or buffer layers) 13, 15 including a buffer material with a working voltage of less than 5.2 eV between the transparent electrode 12 and the photovoltaic layer 14, and/or between the photovoltaic layer 14 and the metal electrode 16.

The buffer material may particularly be chosen from polyethylene dioxythiophene (PEDOT), poly(styrenesulfonate) (PSS), and mixtures thereof.

The buffer layer (or each of the buffer layers) 13, 15 may have a thickness ranging from about 30 nm to 200 nm. In one embodiment, the buffer layer (or each of the buffer layers) 13, 15 may have a thickness ranging from 50 to 100 nm. When the buffer layer (or each of the buffer layers) 13, 15 has a thickness within the above range, it can provide relatively high photoelectric efficiency.

Furthermore, the present invention includes an inter-electrode 17 between the first photovoltaic layer 14a and the second photovoltaic layer 14b. The inter-electrode 17 includes a buffer material with a working voltage of less than 5.2 eV.

This inter-electrode 17 may have a lower work function than that of the metal electrode 16. For example, when the inter-electrode 17 includes PEDOT and PSS, the metal electrode 16 may be formed of Pt or Ni with a higher work function than the inter-electrode 17.

In addition, an electron injection layer 18 may be inserted between the photovoltaic layer 14 and the metal electrode 16, or between the buffer layer 15 and the metal electrode 16 when the buffer layer 15 is formed.

This electron injection layer 18 may be formed from a material selected from the group consisting of calcium; lithium derivatives such as lithium fluoride (LiF), lithium quinolate (LiQ), and the like; and mixtures thereof.

Hereinafter, an operation of a photovoltaic device as an organic solar cell is described in more detail.

First, when solar light is provided through the transparent substrate 10 and the transparent electrode 12, an electron donor (or donating material) produces an electron-hole pair. The electron-hole pair moves to an electron acceptor (or accepting material), where the electron is separated from the hole. Electrons are separated from holes due to a rapid charge movement between the electron donor and the electron acceptor, which is called a photo-induced charge transfer (PICT). The separated electrons and holes are respectively injected into each electrode 12 and 16, thereby producing electrical energy. Since the aforementioned organic solar cell includes an organic material, it can be fabricated as a flexible thin film with a low cost and in a simple manufacturing process.

However, the present invention should not be understood to be limited thereto but can be applied to various kinds of suitable solar cells such as a semi-transparent cell, a tandem cell, and the like, and can also be applied to a suitable optical sensor and so on.

Another embodiment of the present invention provides a method of preparing a photovoltaic device with the aforementioned structure.

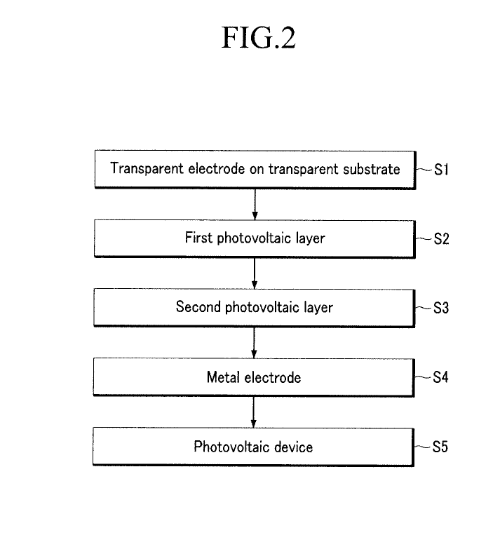

FIG. 2 shows a flow chart schematically showing a manufacturing method of a photovoltaic device according to an embodiment of the present invention. Referring to FIG. 2, the method of manufacturing the photovoltaic device includes forming a transparent electrode on a transparent substrate (S1); forming a first photovoltaic layer including a short-wavelength absorption compound on the transparent electrode (S2); forming a second photovoltaic layer including a long-wavelength absorption compound on the first photovoltaic layer (S3); and forming a metal electrode on the second photovoltaic layer (S4).

More specifically, the transparent electrode is formed on the transparent substrate (S1).

The transparent substrate in this method is the same (or substantially the same) as the aforementioned transparent substrate.

The transparent electrode is formed by disposing the aforementioned conductive metal oxide on the transparent substrate in a suitable method for forming a film such as deposition, slurry coating, and the like.

Next, the first photovoltaic layer including the short-wavelength absorption compound is disposed on the transparent electrode (S2).

The first photovoltaic layer can be formed by coating a composition including the short-wavelength absorption compound, an electron accepting material, and a solvent, and then drying it. Here, the short-wavelength absorption compound and the electron accepting material are the same (or substantially the same) as the aforementioned short-wavelength absorption compound and the aforementioned electron accepting material.

Also, the solvent may be formed from a material selected from the group consisting of water that is capable of dissolving a short-wavelength absorption compound; a hydrocarbon-based solvent such as toluene, xylene, and the like; a halogenated hydrocarbon-based solvent such as chloroform, chlorobenzene, and the like; and mixtures thereof.

The coating method may be selected from the group consisting of a spray coating method, a dipping method, a reverse roll method, a direct roll method, a gravure method, a screen printing method, a doctor blade method, a gravure coating method, a dip coating method, a silk screening method, a painting method, a slot dye coating method, and the like, but is not limited thereto. In one embodiment, the coating method may include the spray coating method.

In addition, the first photovoltaic layer can be optionally treated with plasma (or plasma-treated) after being dried for surface modification.

The plasma treatment can be performed under an inactive gas atmosphere utilizing a substance selected from the group consisting of argon, nitrogen, and combinations thereof, or under an oxidation atmosphere using oxygen. The oxidation atmosphere is convenient for multi-coating, and can facilitate uniform surface-modification of the first photovoltaic layer so that there are no pin holes therein. Also, the plasma treatment can prevent (or reduce) the first photovoltaic layer from losing electrical characteristics due to moisture and oxygen absorbed on the surface during the manufacturing process.

In addition, the plasma treatment can be performed with a source output power ranging from about 1 W to about 30 W (or from 1 W to 30 W). In one embodiment, the plasma treatment can be performed with a source output power ranging from 1 W to 10 W or from 1 W to 5 W. When the source output power is less than 1 W, plasma may not be uniformly formed. When the power is more than 30 W, the surface of a polymer may be destroyed due to the high output.

The plasma treatment can be performed for a time period ranging from about 10 to about 120 seconds (or from 10 to 120 seconds) under the aforementioned conditions. In one embodiment, the plasma treatment can be performed for 10 to 30 seconds. When it is performed for shorter than 10 seconds, the surface treatment may not be properly performed. When the plasma treatment is performed for longer than 120 seconds, it may destroy the surface of a polymer.

The second photovoltaic layer including the long-wavelength absorption compound is then disposed on the first photovoltaic layer surface-treated with plasma (S3).

The second photovoltaic layer can be formed by coating a composition including a long-wavelength absorption compound, an electron accepting material, and a solvent. Here, the long-wavelength absorption compound and the electron accepting material are the same (or substantially the same) as the aforementioned long-wavelength absorption compound and the aforementioned electron accepting material.

The solvent may be formed from a material selected from the group consisting of a hydrocarbon-based solvent such as xylene that can easily dissolve a long-wavelength absorption compound; a halogenated hydrocarbon-based solvent such as chloroform, chlorobenzene, and the like; and mixtures thereof. However, in order to form a plurality of photovoltaic layers, the layer compositions should respectively include different solvents.

The second photovoltaic layer can be formed in the same (or substantially the same) coating method as the first photovoltaic layer.

The metal electrode is then formed on the second photovoltaic layer (S4).

The metal electrode includes a metal with a low work function, and can be formed by suitable method such as vacuum thermal deposition, ion beam deposition, and the like.

Therefore, a photovoltaic device including a plurality of photovoltaic layers can be fabricated by the above manufacturing method.

In addition, the manufacturing method may include a process for forming a buffer layer, an inter-electrode, and/or an electron injection layer, according to whether a photovoltaic device includes a buffer layer, an inter-electrode, and/or an electron injection layer. When a buffer layer and/or an inter-electrode is(are) formed on a photovoltaic layer, the photovoltaic layer can be additionally surface-modified with plasma as aforementioned. The plasma surface treatment can make it easy to coat a hydrophilic material on a non-hydrophilic surface.

The manufacturing method as described above can be utilized to dispose a plurality of photovoltaic layers in a photovoltaic device and/or to uniformly surface-modify a photovoltaic layer during the plasma surface treatment to thereby generate no pin holes and no dark current and/or to prevent deterioration of electron conductivity of the surface-treated photovoltaic layer.

Therefore, a photovoltaic device fabricated according to the manufacturing method includes a plurality of photovoltaic layers having different light absorption regions and can thereby have relatively high photoelectric efficiency.

The following examples illustrate the present invention in more detail. However, the present invention is not limited to the examples, and/or can be applied to various suitable embodiments.

### EXAMPLE 1

A transparent electrode made of indium tin oxide was disposed on a glass substrate. Then, a composition for a buffer layer was prepared by dissolving a mixture of polyethylene dioxythiophene (PEDOT) and poly(styrenesulfonate) (PSS) (1:1 weight ratio). The composition was then disposed on the transparent electrode by a spin coating method. The coating layer was dried at 100° C. in a vacuum oven for 30 minutes to form a buffer layer with a thickness of about 100 nm.

Next, a composition for forming a first photovoltaic layer was prepared by dissolving 20 mg of a pentacene derivative as a short-wavelength absorption compound (the pentacene derivation being bis(triisopropylsilylethynyl) pentacene (TIPS-pentacene)) and 20 mg of a fullerene derivative (PCBM) in 1 ml of toluene. Then, the composition was coated on the buffer layer by a spin coating method and dried to form a 100 nm-thick first photovoltaic layer. Then, the first photovoltaic layer was applied with plasma at a source output power of 1 W for 30 seconds under an argon atmosphere to perform a surface-modifying treatment.

In addition, a composition for a second photovoltaic layer was prepared by dissolving 15 mg of poly(3-hexylthiophene) as a long-wavelength absorption compound and 10 mg of fullerene in 1 ml of chlorobenzene. The composition was coated on the first photovoltaic layer surface-treated with plasma by a spin coating method, and then dried to form a 150 nm-thick second photovoltaic layer.

Then, LiF (lithium fluoride) was disposed on the second photovoltaic layer by a vacuum thermal deposition method to form a 1 nm-thick electron injection layer.

Subsequently, a metal electrode including Al was formed to be 1000 Å thick by a vacuum thermal deposition method, thereby preparing an organic solar cell. The organic solar cell was fabricated at a size of 4 mm×4 mm.

### EXAMPLE 2

A transparent electrode made of indium tin oxide was disposed on a glass substrate. Then, a composition for forming a first buffer layer was prepared by dissolving a mixture of polyethylene dioxythiophene (PEDOT) and poly(styrenesulfonate) (PSS) (1:1 weight ratio) in deionized water on the transparent electrode. The composition was then disposed on the transparent electrode by a spin coating method and dried at 100° C. in a vacuum oven for 30 minutes to form a first buffer layer with a thickness of about 100 nm.

Then, a composition for forming a first photovoltaic layer was prepared by dissolving 20 mg of a pentacene derivative (bis(triisopropylsilylethynyl) pentacene (TIPS-pentacene)) as a short-wavelength absorption compound and 16 mg of fullerene in 2 ml of chlorobenzene. The composition was coated on the buffer layer by a spin coating method and dried to prepare a 120 nm-thick first photovoltaic layer.

Then, a composition for forming a second photovoltaic layer was prepared by dissolving 15 mg of poly(3-octylthiophene) (P3OT) as a long-wavelength absorption compound and 10 mg of fullerene in 1 ml of chlorobenzene. The composition was coated on the first photovoltaic layer by a spin coating method to dispose a 150 nm-thick second photovoltaic layer.

The second photovoltaic layer was applied with plasma at a source output of 1 W for 30 seconds under an argon atmosphere to perform a surface modifying treatment.

Next, a composition for forming a second buffer layer was prepared by dissolving a mixture of polyethylene dioxythiophene (PEDOT) and poly(styrenesulfonate) (PSS) (1:1 weight ratio) in deionized water. The composition was thereafter coated by a spin coating method and dried at 100° C. in a vacuum oven for 30 minutes to dispose a second buffer layer with a thickness of about 100 nm.

Then, a metal electrode including Au was disposed to be 100 Å thick on the second buffer layer by a vacuum thermal deposition method, thereby preparing an organic solar cell. The organic solar cell was fabricated at a size of 4 mm×4 mm.

### EXAMPLE 3

A transparent electrode including indium tin oxide was disposed on a glass substrate. Then, a composition for forming a buffer layer was prepared by dissolving a mixture of polyethylene dioxythiophene (PEDOT) and poly(styrenesulfonate) (PSS) (1:1 weight ratio) in deionized water. The composition was coated by a spin coating method and dried at 100° C. in a vacuum oven for 30 minutes to dispose a buffer layer with a thickness of about 100 nm.

Next, a composition for forming a first photovoltaic layer was prepared by dissolving 20 mg of poly(2-methoxy-5-(3,7-dimethoxyoctyloxy)-1,4-phenylene-vinylene) (MDMO-PPV) as a short-wavelength absorption compound and 20 mg of PCBM in 1 ml of toluene. The composition was coated on the buffer layer by a spin coating method to dispose a 100 nm-thick first photovoltaic layer. The first photovoltaic layer was applied with plasma at a source output of 1 W under a nitrogen atmosphere for 30 seconds to perform a surface modifying treatment.

Then, a composition for forming an inter-electrode was prepared by dissolving a mixture of polyethylene dioxythiophene (PEDOT) and poly(styrenesulfonate) (PSS) (1:1 weight ratio) in deionized water. The composition was coated on the first photovoltaic layer treated with plasma by a spin coating method and dried at 100° C. in a vacuum oven for 30 minutes to form an inter-electrode with a thickness of about 100 nm.

Then, a composition for a second photovoltaic layer was prepared by dissolving 20 mg of poly[2,6-(4,4-bis-(2-ethylhexyl)-4H-cyclopenta[2,1-b;3,4-b′]-dithiophene)-alt-4,7-(2,1,3-benzothiadiazole)] (PCPDTBT) as a long-wavelength absorption compound and 20 mg of fullerene in 2 ml of chlorobenzene. The composition was coated on the inter-electrode by a screen printing method and dried to form a 120 nm-thick second photovoltaic layer.

Then, LiF (lithium fluoride) was disposed on the second photovoltaic layer by a vacuum thermal deposition method to form an electron injection layer with a thickness of about 1 nm.

Subsequently, a metal electrode including Al was disposed to be 1000 Å thick by a vacuum thermal deposition method, thereby preparing an organic solar cell. The organic solar cell was fabricated at a size of 4 mm×4 mm.

### COMPARATIVE EXAMPLE 1

A transparent electrode including indium tin oxide was disposed on a glass substrate. Then, a composition for forming a buffer layer was prepared by dissolving a mixture of polyethylene dioxythiophene (PEDOT) and poly(styrenesulfonate) (PSS) (1:1 weight ratio) in deionized water. The composition was coated by a spin coating method and dried at 100° C. in a vacuum oven for 30 minutes to form a buffer layer with a thickness of about 100 nm.

Next, a composition for forming a first photovoltaic layer was prepared by dissolving 20 mg of poly(2-methoxy-5-(3,7-dimethoxyoctyloxy)-1,4-phenylene-vinylene) (MDMO-PPV) as a short-wavelength absorption compound and 20 mg of PCBM in 1 ml of toluene. The composition was coated on the buffer layer by a spin coating method and dried to form a 100 nm-thick first photovoltaic layer.

Then, an ITO layer was disposed on the first photovoltaic layer under vacuum by an electronic beam deposition method to prepare an inter-electrode.

In addition, a composition for forming a second photovoltaic layer was prepared by dissolving 20 mg of poly(2-methoxy-5-(3,7-dimethoxyoctyloxy)-1,4-phenylene-vinylene) (MDMO-PPV) and 20 mg of PCBM in 1 ml of toluene. The composition was coated by a spin coating method and dried to form a 120 nm-thick second photovoltaic layer.

Then, LiF (lithium fluoride) was disposed on the second photovoltaic layer by a vacuum thermal deposition method to form an electron injection layer with a thickness of about 1 nm.

Subsequently, a metal electrode including Al was formed to be 1000 Å thick by a vacuum thermal deposition method, thereby preparing an organic solar cell. The organic solar cell was fabricated at a size of 4 mm×4 mm.

The voltage-current (V-I) characteristics of the organic solar cells according to Examples 1 to 3 and Comparative Example 1 were measured. Their open-circuit voltage (Voc), short-circuit current density (Jsc, mA/cm²), and fill factor (FF, %) were calculated based on a curved line of the measured V-I characteristics. Their photoelectric efficiency (η, %) was also evaluated.

Herein, a xenon lamp of Oriel, 01193, was used as a light source, and the solar condition (AM 1.5) of the xenon lamp was corrected by using a standard solar cell (Frunhofer Institute Solare Engeriessysteme, Certificate No. C-ISE369, type of material: Mono-Si+KG filter).

The fill factor is a value obtained by dividing Vmp×Jmp, where Vmp is a current density and Jmp is a voltage at a maximal electric power voltage, by Voc×Jsc. The photovoltaic efficiency (η) of a solar cell is the conversion efficiency of solar energy to electrical energy, which can be obtained by dividing a solar cell electrical energy (current×voltage×fill factor) by energy per unit area (P_{inc}) as shown in the following Equation 1.

η=(Voc·Jsc·FF)/(P_{inc}) Equation 1

wherein the P_{inc} is 100 mW/cm² (1 sun).

As a result, the organic solar cells according to Examples 1 to 3 were found to have 10 to 50% improved photoelectric efficiency as compared with Comparative Example 1. The reason that although the organic solar cell of Comparative Example 1 includes a plurality of photovoltaic layers, it still has a low absorption rate for light with a long wavelength is because the organic solar cell of Comparative Example 1 includes light-absorbing compounds for absorbing the same short light absorption wavelength region. In addition, the organic solar cell of Comparative Example 1 has a low electron emission characteristic, partly because the first photovoltaic layer formed of a polymer was damaged during the electronic beam deposition process for forming the inter-electrode.

The present invention was illustrated based on an organic solar cell. It should be understood that the organic solar cell is one example of a photovoltaic device, and the present invention is not limited thereto and can be applied into various suitable photovoltaic devices.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A photovoltaic device comprising:
a transparent electrode;
a metal electrode; and
a plurality of photovoltaic layers between the transparent electrode and the metal electrode,
wherein the photovoltaic layers comprise light-absorbing compounds for absorbing different light absorption wavelength bands, and
wherein each of the photovoltaic layers comprises an electron accepting material.

2. The device of claim 1, wherein the photovoltaic layers comprise:
a first photovoltaic layer comprising a short-wavelength absorption compound on the transparent electrode; and
a second photovoltaic layer comprising a long-wavelength absorption compound on the metal electrode.

3. The device of claim 2, wherein a thickness ratio between the first photovoltaic layer comprising the short-wavelength absorption compound and the second photovoltaic layer comprising the long-wavelength absorption compound ranges from about 1:1 to about 1:3.

4. The device of claim 2, wherein the first photovoltaic layer comprising the short-wavelength absorption compound has a thickness ranging from about 30 nm to about 150 nm.

5. The device of claim 2, wherein the short-wavelength absorption compound is for absorbing light having a wavelength ranging from about 400 nm to about 600 nm.

6. The device of claim 2, wherein the short-wavelength absorption compound comprises a hydrophilic conductive compound selected from the group consisting of a polyphenylenevinylene-based polymer, a pentacene compound, and mixtures thereof.

7. The device of claim 2, wherein the short-wavelength absorption compound is included in the first photovoltaic layer in an amount ranging from 20 to 400 parts by weight based on 100 parts by weight of the electron accepting material.

8. The device of claim 2, wherein the second photovoltaic layer comprising the long-wavelength absorption compound has a thickness ranging from about 30 nm to about 200 nm.

9. The device of claim 2, wherein the long-wavelength absorption compound is for absorbing light having a wavelength ranging from about 400 nm to about 900 nm.

10. The device of claim 2, wherein the long-wavelength absorption compound comprises a non-hydrophilic conjugated polymer selected from the group consisting of a thiophene-based polymer, a dithiophene-based polymer, and mixtures thereof.

11. The device of claim 2, wherein the long-wavelength absorption compound is included in the second photovoltaic layer in an amount ranging from 20 to 400 parts by weight based on 100 parts by weight of the electron accepting material.

12. The device of claim 1, wherein the electron accepting material is selected from the group consisting of fullerene, fullerene derivatives, perylene, carbon nanotubes, semiconductor nanoparticles, and mixtures thereof.

13. The device of claim 1, further comprising a buffer layer between the transparent electrode and photovoltaic layer, or between the photovoltaic layer and the metal electrode, the buffer layer comprising a material with a working voltage of 5.2 eV or less.

14. The device of claim 13, wherein the material in the buffer layer is selected from the group consisting of poly(3,4-ethylenedioxythiophene), poly(styrene-sulfonate), and mixtures thereof.

15. The device of claim 1, further comprising an inter-electrode between the photovoltaic layers, the inter-electrode comprising a material with a working voltage of 5.2 eV or less.

16. The device of claim 1, further comprising an electron injection layer between the metal electrode and the photovoltaic layers.

17. The device of claim 16, wherein the electron injection layer comprises a material selected from the group consisting of calcium, lithium derivatives, and mixtures thereof.

18. The device of claim 1, wherein the photovoltaic device is a solar cell or an organic optical sensor.

19. A method of manufacturing a photovoltaic device, the method comprising:
forming a transparent electrode on a transparent substrate;
forming a first photovoltaic layer comprising a short-wavelength absorption compound and an electron accepting material on the transparent electrode;
forming a second photovoltaic layer comprising a long-wavelength absorption compound and an electron accepting material on the first photovoltaic layer; and
forming a metal electrode on the second photovoltaic layer.

20. The method of claim 19, wherein the short-wavelength absorption compound is for absorbing light having a wavelength ranging from about 400 nm to about 600 nm.

21. The method of claim 19, wherein the method further comprises a plasma surface treatment after the forming of the first photovoltaic layer.

22. The method of claim 21, wherein the plasma treatment is performed under an inactive gas or oxidation atmosphere.

23. The method of claim 21, wherein the plasma treatment is performed utilizing a power ranging from about 1 W to about 30 W.

24. The method of claim 21, wherein the plasma treatment is performed for a time period ranging from about 10 to about 120 seconds.

25. The method of claim 19, wherein the long-wavelength absorption compound is for absorbing light having a wavelength ranging from about 400 to about 900 nm.
